(19) United States
(12) Patent Application Publication
(10) Pub. No.: US 2014/0320115 A1
(43) Pub. Date: Oct. 30, 2014

(54) ROTATION ANGLE DETECTOR

(71) Applicant: AISAN KOGYO KABUSHIKI KAISHA, Obu-shi (JP)

(72) Inventors: Makoto MASE, Handa-shi (JP); Toshiya YOKOI, Okazaki-shi (JP); Yasuhiro NISHIKAWA, Tokai-shi (JP)

(73) Assignee: AISAN KOGYO KABUSHIKI KAISHA, Obu-shi (JP)

(21) Appl. No.: 14/259,822

(22) Filed: Apr. 23, 2014

(30) Foreign Application Priority Data
Apr. 25, 2013 (JP) 2013-092286

(51) Int. Cl. G01B 7/30; G01R 33/02

(52) U.S. Cl. CPC G01B 7/30; G01R 33/02
USPC 324/207.13; 324/207.25

(57) ABSTRACT

A rotation angle detector for detecting the magnetic change caused by rotation of a rotatable member, has a resin molding, a pair of magnetic property detection members, and a plurality of sensor terminals. Each of the magnetic property detection members has a sensor portion for detecting the magnetic change caused by the rotatable member and a plurality of connecting leads. The sensor terminals are individually connected to each connecting lead. The magnetic property detection members are located within in the resin molding. The sensor portions of the magnetic property detection members are fixedly coupled to each other by an adhesive.

### CROSS-REFERENCES TO RELATED APPLICATIONS

This application claims priority to Japanese patent application serial number 2013-092286, filed on Apr. 25, 2013, the contents of which are incorporated herein by reference in its entirety for all purposes.

### BACKGROUND

This application relates to a rotation angle detector for detecting the rotational angle of a rotatable member.

Japanese Laid-Open Patent Publication No. 2007-92608 discloses a rotation angle detector having a pair of magnetic property detection members each having connection leads, a plurality of sensor terminals connected to the connection leads, and a resin molding for fixing the magnetic property detection members. The resin molding is molded using an insertion molding method. In accordance with the Japanese Laid-Open Patent Publication No. 2007-92608, a retaining member is fixed on the sensor terminals in order to decrease the position gap of the magnetic property detection members.

According to Japanese Laid-Open Patent Publication No. 2007-92608, because the retaining member for positioning the magnetic property detection members is required, the number of members and thus amount of work required for assembly increases.

### SUMMARY OF THE DISCLOSURE

In one aspect of this disclosure, a rotation angle detector for detecting magnetic change caused by rotation of a rotatable member, has a resin molding, a pair of magnetic property detection members, and a plurality of sensor terminals. Each of the magnetic property detection members has a plurality of connecting leads and a sensor portion detecting the magnetic change caused by the rotatable member. The sensor terminals are connected to the connecting leads, respectively. The magnetic property detection members are located within the resin molding. The sensor portions of the magnetic property detection members are fixedly coupled to each other by an adhesive. In accordance with this configuration, the sensor portions are fixedly coupled to each other by the adhesive and thus a retaining member is not needed as in conventional practice. In this way, the number of components and the number of manufacturing steps can be decreased.

### BRIEF DESCRIPTION OF THE DRAWINGS

FIG. 1 is a cross-sectional view of a rotational angle sensor and its surrounding parts according to one embodiment;

FIG. 2 is a front view of the rotational angle sensor;

FIG. 3 is a top view of the rotational angle sensor;

FIG. 4 is a cross-sectional view of the rotational angle sensor;

FIG. 5 is a front view of a sensor IC;

FIG. 6 is a front view of a pair of the assembled sensor ICs;

FIG. 7 is a top view of the pair of the assembled sensor ICs;

FIG. 8 is a front view showing the positioned sensor ICs in a weld process of sensor terminals;

FIG. 9 is a top view showing the positioned sensor ICs in the weld process of the sensor terminals;

FIG. 10 is a cross-sectional view showing the positioned sensor ICs in the weld process of the sensor terminals;

FIG. 11 is a cross-sectional view along XI-XI line shown in FIG. 8;

FIG. 12 is a sectional front view of a mold;

FIG. 13 is a sectional side view of the mold;

FIG. 14 is a top view of a molded sensor product;

FIG. 15 is a sectional front view of the molded sensor product;

FIG. 16 is a sectional side view of the molded sensor product; and

FIG. 17 is a sectional front view of a mold for a next process.

### DETAILED DESCRIPTION

Each of the additional features and teachings disclosed above and below may be utilized separately or in conjunction with other features and teachings to provide improved rotation angle detectors. Representative examples, which examples utilize many of these additional features and teachings both separately and in conjunction with one another, will now be described in detail with reference to the attached drawings. This detailed description is merely intended to teach a person of ordinary skill in the art further details for practicing preferred aspects of the present teachings and is not intended to limit the scope of the disclosure. Only the claims define the scope of the claimed invention. Therefore, combinations of features and steps disclosed in the following detailed description may not be necessary to practice the invention in the broadest sense, and are instead taught merely to particularly describe representative examples thereof. Moreover, various features of the representative examples and the dependent claims may be combined in ways that are not specifically enumerated in order to provide additional useful embodiments of the present teachings.

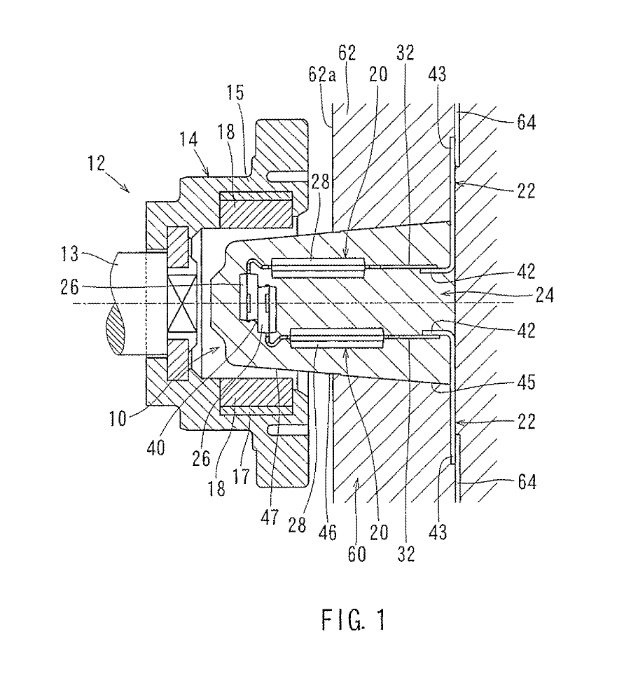

One embodiment will be described in view of the drawings. FIG. 1 is a cross-sectional view showing a rotational angle sensor 10 and its surrounding parts. As shown in FIG. 1, the rotational angle sensor 10 is configured to detect a rotational angle of a rotatable member 12 and is fixedly mounted on a connector side member 60 (described below) as a securing member. The rotatable member 12 has a rotary shaft 13 and a rotating body 14, which is attached to one end of the rotary shaft 13 such that the rotating body 14 cannot rotate around the rotary shaft 13. The rotary shaft 13 is held such that the rotary shaft 13 can rotate with respect to a supporting member (not shown) fixedly provided. The rotating body 14 rotates together with the rotary shaft 13. The rotating body 14 has a hollow cylinder portion 15, which is made from, e.g., a resin material and concentrically extrudes in an opposite direction (rightward in FIG. 1) to the rotary shaft 13. The cylinder portion 15 has on its inner circumference a hollow cylinder-shaped yoke 17 and a pair of permanent magnets 18 mounted on the inner periphery of the yoke 17, which are integrated with each other. The yoke 17 is made from a magnetic material. The pair of the permanent magnets 18 are made of, e.g., ferrite magnets and are mounted in a parallel fashion in order to generate a substantially parallel magnetic field between the permanent magnets 18, that is, a space (magnetic field) in the cylinder portion 15.

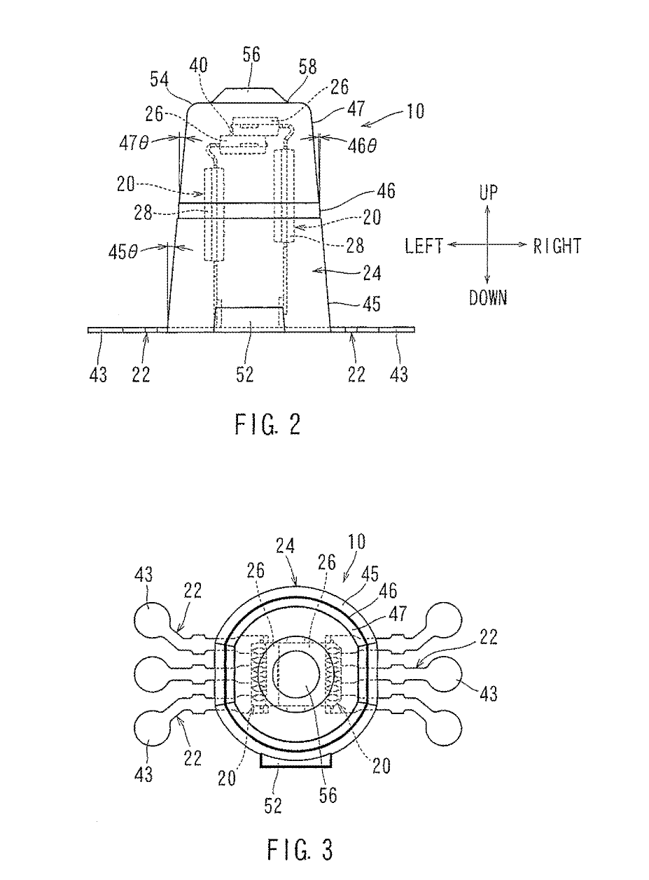

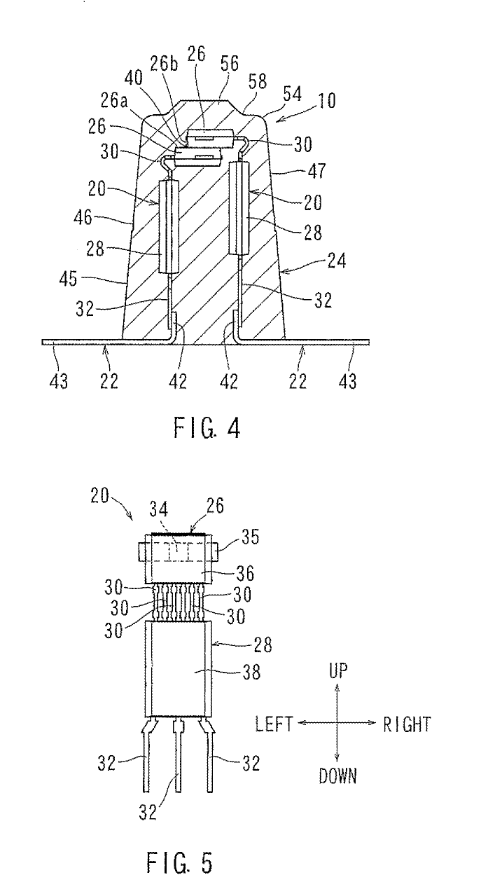

FIG. 2 is a front view of the rotational angle sensor 10. FIG. 3 is a top view of the rotational angle sensor 10. FIG. 4 is a sectional front view of the rotational angle sensor 10. For convenience of explanation, the rotational angle sensor 10 will be described based on upper, lower, right and left directions shown in FIG. 2. As shown in FIG. 4, the rotational angle sensor 10 has a pair of the sensor Integrated Circuits (“IC”s) 20, a plurality of (for example, six) sensor terminals 22, and a resin molding 24 in which the sensor ICs 20 are located. It should be appreciated that the rotational angle sensor 10 may be referred to herein as a “rotation angle detector.”

The sensor IC 20 will be described. FIG. 5 is a front view of the sensor IC 20. FIG. 5 shows a condition that coupling leads 30 have not been bent. Here, the sensor IC 20 will be described based on upper, lower, right and left directions shown in FIG. 5. As shown in FIG. 5, the sensor IC 20 is configured as, e.g., a sensor IC including a ferromagnetic MRE (magnetic resistance element). The sensor IC 20 has a sensor portion 26, a computing portion 28, a plurality of (for example, six) the coupling leads 30, and a plurality of (for example, three) connecting leads 32.

In the sensing portion 26, a square-plate shaped bridge channel portion 34 consisting of a ferromagnetic MRE (magnetic resistance element) is disposed on a center of a band-shaped metal retaining plate 35 in the longitudinal direction and is molded in, i.e., located within a resin covering member 36. The covering member 36 is formed in a rectangular plate shape elongating in the horizontal direction in FIG. 5. In FIG. 5, the thickness direction of the covering member 36 is identical to the front-back direction, that is, its width direction is identical to the right-left direction. Both ends of the retaining plate 35 protrude from both side surfaces of the covering member 36 in the right-left direction. It should be appreciated that the covering member 36 may be referred to herein as a “resinous coating.”

In the computing portion 28, a semiconductor integrated circuit (not shown) is molded in, i.e., located within a square-plate shaped covering member 38 made from a resin material. The covering member 38 is formed in a rectangular shape elongated in the vertical direction in FIG. 5. The computing portion 26 is positioned below the sensor portion 26. In FIG. 5, the thickness direction of the covering member 38 is identical to the front-back direction, i.e., the width direction is identical to the right-left direction. The covering member 36 of the sensor portion 26 and the covering member 38 of the computing portion 28 have the same or the substantially same thickness and the same or the substantially same width. It should be appreciated that the covering member 38 may also be referred to herein as a “resinous coating.”

The six coupling leads 30 mechanically and electrically couple the sensor portion 26 (in detail, the bridge channel portion 34) with the computing portion 28 (in detail, the semiconductor integrated circuit). The coupling leads 30 extend between surfaces of the sensing portion 26 and the computing portion 28, which face each other in FIG. 5. The coupling leads 30 are positioned at a center of the sensor portion 26 and the computing portion 28 in the thickness direction and are arranged in parallel at certain intervals in the right-left direction. The coupling leads 30 are made of a metal material having conductive properties such as copper alloy.

The three connecting leads 32 are electrically connected to the computing portion 28 (in detail, the semiconductor integrated circuit) and extrude from a bottom surface of the computing portion 28, that is, an opposite surface to the top surface to which the coupling leads 30 are connected. The connecting leads 32 are positioned at a center of the computing portion 28 in the thickness direction and are arranged in parallel at certain intervals in the right-left direction. The connecting leads 32 are made of a metal material, such as copper alloy, which has conductive properties. The covering member 36 of the sensor portion 26, the covering member 38 of the computing portion 28, the coupling leads 30 and the connecting leads 32 have the same (or substantially the same) linear expansion coefficient.

For use of the sensor ICs 20, the coupling leads 30 are bent such that each of the sensor ICs 20 including the sensor portion 26 and the computing portion 28 is formed in an L-shape (FIG. 4). It should be appreciated that the sensor IC 20 may be referred to herein as a “magnetic property detection member.” The sensor ICs 20 are used such that each of the connecting leads 32 is not bent in the thickness direction and is kept in a linear shape.

The rotational angle sensor 10 has a pair of sensor ICs 20 (FIG. 4). The sensor ICs 20 are positioned to face each other such that their sensor portions 26 are arranged in the thickness direction (i.e., the vertical direction in FIG. 4) and contact each other. In this embodiment, the sensor portion 26 of the right sensor IC 20 is mounted on the sensor portion 26 of the left sensor IC 20. Due to this configuration, the bridge channels 34 of the sensor portions 26 of the sensor ICs 20 are concentrically positioned. The reason for using two sensor ICs 20 is that even if one of the sensor ICs 20 breaks down, the other sensor IC 20 can be used for detection as a fail-safe.

The sensor portions 26 of the sensor ICs 20 are fixedly attached to each other with an adhesive 40. The adhesive 40 binds a top surface 26a of the lower sensor portion 26 to an end surface 26b of the upper sensor portion 26 at an L-shaped inner corner formed by the top surface 26a and the end surface 26b in a state where the sensor portions 26 of the sensor ICs 20 are arranged in their thickness direction.

The sensor terminals 22 will be described. As shown in FIG. 3, six sensor terminals 22, in detail, two sets of three sensor terminals 22 are positioned on a plane surface in a symmetric manner in the horizontal direction. Each set of three sensor terminals 22 are arranged in parallel in the front-back direction (the vertical direction in FIG. 3) in a state where their thickness direction is identical to the vertical direction (the front-back direction of the drawing in FIG. 3). The sensor terminals 22 are made of a metal material such as brass which has conductive properties.

As shown in FIG. 4, each of the sensor terminals 22 has a terminal area 42 on the sensor IC 20 side and a terminal area 43 on a connector side. Each of the terminal areas 42 of the sensor terminals 22 is bent upward in an L-shape. The terminal areas 42 of the left sensor terminals 22 overlap with and are fixedly connected to the lower ends of the connecting leads 32 of the left sensor IC 20 by, e.g., welding. The terminal areas 42 of the right sensor terminals 22 overlap with and are fixedly connected to the lower ends of the connecting leads 32 of the right sensor IC 20 by, e.g., welding. It should be appreciated that the terminal area 43 on the connector side may be referred to herein as an “end on a side opposite the magnetic property detection member side.”

As shown in FIG. 3, the terminal areas 43 on the connector side of the sensor terminals 22 of each set are arranged at certain intervals in the front-back direction (the vertical direction in FIG. 3). An end portion of the front sensor terminal 22 of each set, which includes the terminal area 43, extends diagonally forward (diagonally downward in FIG. 3) such that a distance between the terminal area 43 of the front sensor terminal 22 and the terminal area 43 of the center sensor terminal 22 is increased. Due to this configuration, the front sensor terminal 22 is longer than the center sensor terminals 22.

The sensor terminal 22 on the rear side (the upper side in FIG. 3) of each set is formed in a symmetric manner with the front sensor terminal 22. Both are formed about the center sensor terminal 22. Thus, the distance between the terminal area 43 of the center sensor terminal 22 and the terminal area 43 of the rear sensor terminal 22 is increased, and the rear sensor terminal 22 is longer than the center sensor terminal 22. Each of the terminal areas 43 of the sensor terminals 22 is formed in a round shape having a diameter longer than the width of each sensor terminal 22 (the distance in the perpendicular direction to the longitudinal direction).

The resin molding 24 will be described. As shown in FIGS. 2 and 3, the resin molding 24 is formed in a column shape. In detail, it is a truncated cone shape tapering from a bottom end toward a top end. The resin molding 24 is concentrically formed with the sensor portions 26 (in detail, the bridge channel portions 34) of the sensor ICs 20. The entire sensor ICs 20 are located within the resin molding 24 together with the terminal area 42 of each sensor terminal 22 and its surrounding area (FIG. 4). Thus, the sensor ICs 20 are kept in place. The resin molding 24 has the same (or substantially same) linear expansion coefficient with that of the covering members 36 of the sensing portions 26 of the sensor ICs 20. That is, the covering members 36 of the sensor portions 26, the covering members 38 of the computing portions 28, the coupling leads 30, the connecting leads 32 and the resin molding 24 have the same (or substantially the same) linear expansion coefficient.

As shown in FIG. 2, the resin molding 24 has three tapered sections continuing in an axial direction (the vertical direction), i.e., a lower tapered section 45, a middle tapered section 46 and an upper tapered section 47. An outer circumference of the middle tapered section 46 is formed in a ring shape at a center in the axial direction (the vertical direction) of the resin molding 24. A taper angle 46θ of the middle tapered section 46 is smaller than a taper angle 45θ of the lower tapered section 45 and a taper angle 47θ of the upper tapered section 47. For example, the taper angle 46θ of the middle tapered section 46 is set at 1°, and the taper angle 45θ of the lower tapered section 45 and the taper angle 47θ of the upper tapered section 47 are set at 5°, respectively.

A convex 52 protrudes from a front surface of a lower end of the resin molding 24 (FIGS. 2 and 3). The convex 52 has a rectangular cross-section elongating horizontal direction. An outer circumferential surface and a top end surface (an end surface on the smaller diameter side) of the resin molding 24 are smoothly continued via a convex curved area 54 having a predetermined radius (FIGS. 2 and 4). The top end surface of the resin molding 24 has a projection 56 formed in a truncated cone shape. The top end surface of the resin molding 24 and an outer circumference of the projection 56 are smoothly continued via a concave curved area 58 having a predetermined radius. Right and left side surfaces of the resin molding 24 are flattened and are parallel to each other (FIG. 3).

As shown in FIG. 1, the rotational angle sensor 10 is integrated with a member 60 on the connecter side by the insert molding. A base end (on a large diameter side) of the resin molding 24 including the sensor terminals 22 of the rotational angle sensor 10 is located within a resin molding 62 of the connecter side member 60. A top end (on a small diameter side) of the resin molding 24 of the rotational angle sensor 10 protrudes from a surface 62a of the resin molding 62 of the connector side member 60. The surface 62a of the resin molding 60 is perpendicular to or substantially perpendicular to the axis of the resin welding 24 at a center of the middle tapered section 46 of the resin molding 24 of the rotational angle sensor 10 in the axial direction.

A plurality of connector terminals 64 are located within the resin molding 62 of the connector side member 60. Before forming of the resin molding 62, the terminal area 43 of each sensor terminal 22 is connected to one end (in detail, a terminal for connecting to the sensor) of each connector terminal 64 by, e.g., welding. The opposite end of each connector terminal 64 is exposed at a connecting portion formed on the resin molding 62. It should be appreciated that the connector terminal 64 may be referred to herein as a “wiring member.”

The connector side member 60 is fixedly mounted on a member supporting the rotary shaft 13 of the rotatable member 12 or on another fixedly provided member (not shown). Thus, the top end of the resin molding 24 of the rotational angle sensor 10 is concentrically positioned with respect to the cylinder portion 15 of the rotating body 14 of the rotatable member 12. They are positioned in a non-contact state where a predetermined distance is kept between the top end of the resin molding 24 and an inner circumference of the cylinder portion 15. An external connector linked to a control device is connected to the connecting portion of the member 60. It should be appreciated that the connector side member 60 may be referred to herein as either a “fixed side member” or a “member provided with the rotation angle detector”.

The sensor portions 26 (in detail, the bridge channel portions 34) of the sensor ICs 20 of the rotational angle sensor 10 detect magnetic change generated between the pair of permanent magnets 18 of the rotating body 14 of the rotatable member 12. The computing portion 28 (in detail, the semiconductor integrated circuit) of each sensor ICs 20 outputs signals according to the magnetic change based on detection signals output from the corresponding sensor portion 26. The control device (not shown) computes rotational angle of the rotatable member 12 based on the signals output from the computing portions 28 of the sensor ICs 20.

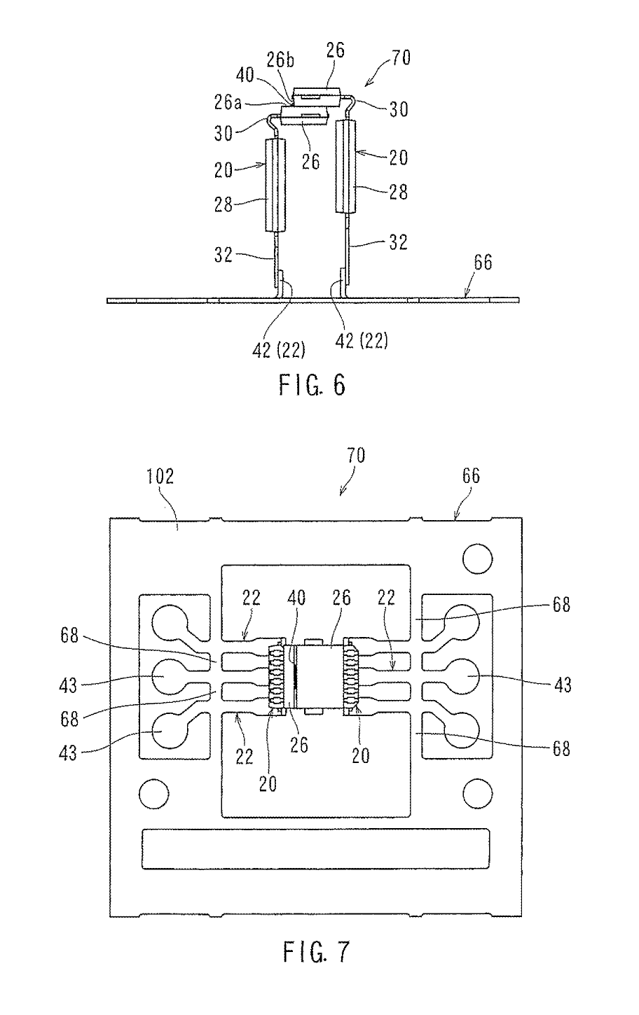

Next, a method for manufacturing the rotational angle sensor 10 will be described. FIG. 6 is a front view of the assembled sensor ICs 20. FIG. 7 is a top view of the assembled sensor ICs 20. As shown in FIG. 7, a hoop material 66 made of a metal plate having conductive properties is provided. The sensor terminals 22 have been shaped on the hoop material 66 by press forming. In the hoop material 66, the sensor terminals 22 are linked to each other via tie-bars 68. As shown in FIG. 6, the terminal area 42 of each sensor terminal 22 is bent upward in the press forming step. The terminal areas 42 are connected to the connecting lead 32 of the sensor ICs 20 by, e.g., welding, respectively. An assembled product of the hoop material 66 and the sensor ICs 20 is referred to as a sensor IC assembly 70.

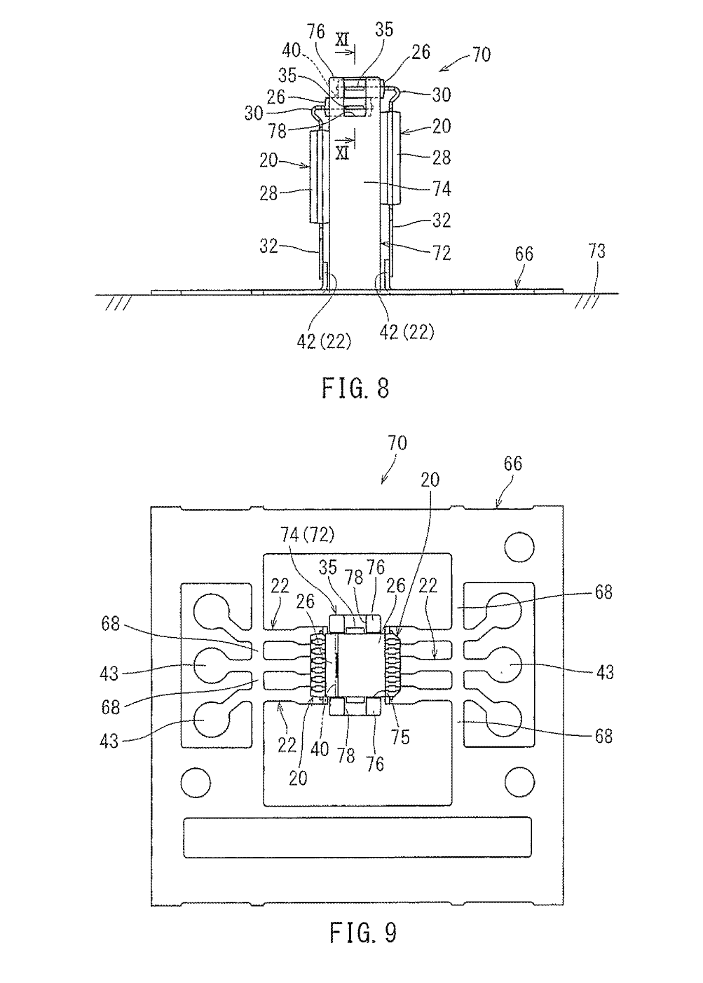

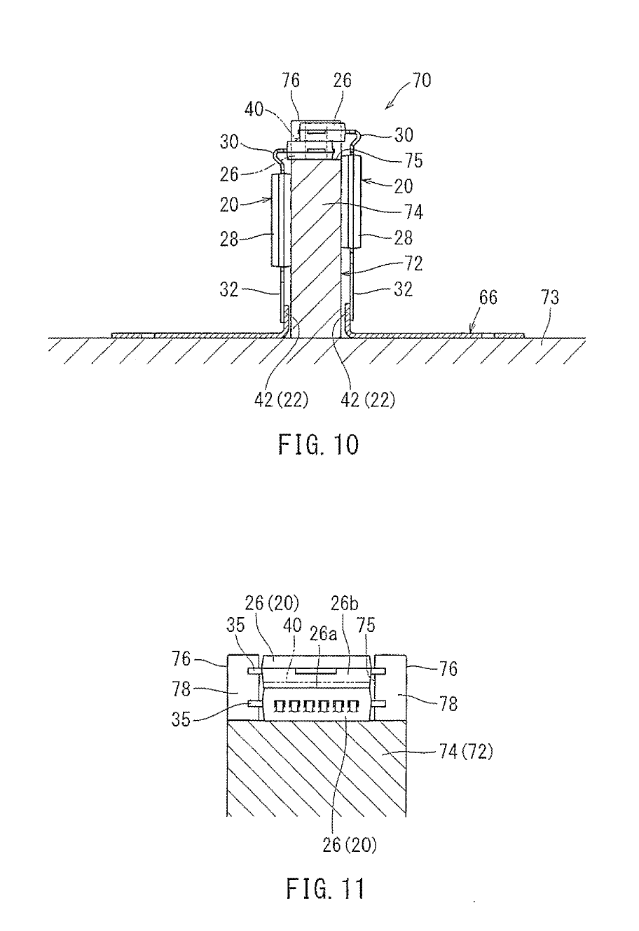

A jig used for connecting the ICs 20 to the sensor terminals 22 of the hoop material 66 will be described. FIG. 8 is a front view showing a state where the sensor ICs 20 are positioned for welding of the sensor terminals 22. FIG. 9 is a top view of the same state. FIG. 10 is a sectional front view of the same state. FIG. 11 is a cross-sectional view along line XI-XI shown in FIG. 8.

As shown in FIG. 10, the jig 72 includes a platform 73 and a support strut 74 installed upright on the platform 73. A concave groove 75 having a U-shaped cross-section and extending in the right-left direction is formed on a top end of the support strut 74. At both walls 76 in front of and in the back of the concave groove 75, front and rear positioning grooves 78 each having a U-shaped cross-section and extending in the front-back direction are formed (FIGS. 8 and 9).

The hoop material 66 is put on the platform 73 of the jig 72 in order to position the hoop material 66 (FIG. 8). The hoop material 66 is fitted with the support strut 74 such that the terminal areas 42 of the right sensor terminals 22 are placed on the right side of the support strut 74 of the jig 72 and the terminal areas 42 of the left sensor terminals 22 are placed on the left side of the support strut 74 of the jig 72 (FIG. 8). Then, the sensor portions 26 of the sensor ICs 20 are fitted downward into the concave groove 75 of the support strut 74 of the jig 72. As a result, both ends of the retaining plate 35 of the sensor portion 26 of each sensor IC 20 are placed in the positioning grooves 78 formed in the walls 76 (FIGS. 8-11). Further, each of the computing portions 28 of the sensor ICs 20 is placed to face either side of the support strut 74 and close to or in contact with the corresponding side of the support strut 74 (FIGS. 8 and 10). In this way, the sensor ICs 20 are positioned on the jig 72.

In this state, the adhesive 40 is applied to the L-shaped inner corner formed by the top surface 26a and the end surface 26b in a state where the sensor portions 26 of the sensor ICs 20 are arranged and contact each other in their thickness direction (FIGS. 10 and 11). After hardening of the adhesive 40, the adhesive 40 fixedly couples the upper surface 26a of the lower sensor portion 26 to the end surface 26b of the upper sensor portion 26.

The connecting leads 32 of the sensor ICs 20 positioned on the jig 72 overlap with the terminal areas 42 of the sensor terminals 22 of the hoop material 66, respectively (FIG. 10). In this state, each of the connecting leads 32 is coupled with the terminal area 42 of each sensor terminal 22 by, e.g., welding. As described above, the sensor IC assembly 70 is made up by assembling the hoop material 66 and the sensor ICs 20. The sensor IC assembly 70 is lifted upward along the support strut 74 of the jig 72 in order to remove the sensor IC assembly 70 from the jig 72.

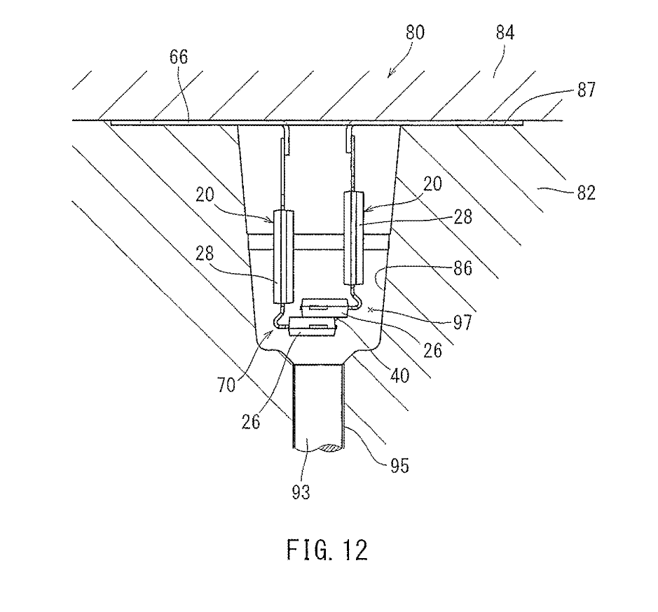

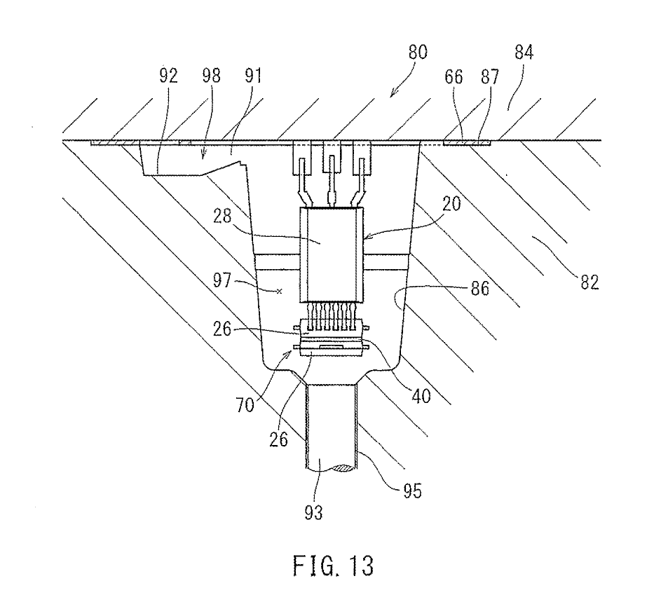

Next, a forming method of the resin molding 24 of the rotational angle sensor 10 will be described. First, a shaping die, i.e., a mold 80 for insert molding of the resin molding 24 with the sensor IC assembly 70 using a resin material (a melting resin) will be described. FIG. 12 is a sectional front view of the mold 80. FIG. 13 is a sectional side view of the mold 80. As shown in FIG. 12, the mold 80 is composed of a lower mold 82 and an upper mold 84. In this embodiment, the lower mold 82 is fixed, and the upper mold 84 is movable. The upper mold 84 can be moved in the vertical direction. That is, when the upper mold 84 is moved downward with respect to the lower mold 82, the mold 80 is closed. When the upper mold 84 is moved upward with respect to the lower mold 82, the mold 80 is opened. A lower surface of the upper mold 84, i.e., matching surface is formed in a flat shape extending in the horizontal direction.

The lower mold 82 has a shaping recess 86 formed in a hollow cylinder shape with a bottom for shaping an outer surface of the resin molding 24 of the rotational angle sensor 10 (except for its end surface on the large diameter side and the positioning recess 87 for fitting with the hoop material 66 (including punched holes)). On an upper surface of the lower mold 82, (i.e., a matching surface) a recessed resin-flow groove 92 having a gate 91 extends in the right-left direction, which corresponds to the convex 52 of the resin molding 24 (refer to FIG. 3), is formed (FIG. 13).

As shown in FIGS. 12 and 13, an ejection rod 93 formed in a round bar shape is provided movably in the vertical direction on a bottom side of the shaping recess 86 of the lower mold 82, i.e., a side for shaping the top end of the projection 56 of the resin molding 24. When the ejection rod 93 is refracted in a lower position, a top end surface of the ejection rod 93 matches (or substantially matches) with a bottom end surface of the shaping recess 86. The ejection rod 93 is moved upward and downward by a drive mechanism (not shown). A gas-vent passage 95 formed in a cylinder shape having a ring cross-section is formed between the lower mold 82 and the ejection rod 93. The gas-vent passage 95 is open to the outside (the atmosphere) on the lower side. It should be appreciated that the upper mold 84 and the lower mold 82 may each be referred to herein as a “mold component.” In addition, it should also be appreciated that the lower mold 82 may be referred to herein as a “mold component having the ejection rod.”

A forming method of the resin molding 24 of the rotational angle sensor 10 by the mold 80 will be described. In a state where the mold 80 is opened, the sensor IC assembly 70 (refer to FIGS. 6 and 7) is turned upside-down on the lower mold 82. That is, the hoop material 66 is fitted into the positioning recess 87 while inserting the sensor ICs 20 of the sensor IC assembly 70 into the shaping recess 86 of the lower mold 82. Thus, the hoop material 66 is positioned by the positioning recess 87, and the sensor ICs 20 are located at predetermined positions in the shaping recess 86. In this state, because both of the sensor portions 26 are fixedly coupled to each other, the sensor ICs 20 are positioned at the predetermined positions.

After the sensor IC assembly 70 is set on the lower mold 82, the lower mold 82 is fitted with the upper mold 84 for closing the mold 80. As a result, a cavity 97 for shaping the resin molding 24 is formed between the upper mold 84 and the lower mold 82, and the hoop material 66 (with the exception of the surrounding area around the cavity 97) is held between the upper mold 84 and the lower mold 82. Because an upper open side of the resin-flow groove 92 is closed by the upper mold 84, a resin passageway 98 is formed between the upper mold 84 and the lower mold 82 (FIG. 13). In this state, a resin injection unit (not shown) injects a resin material (melting resin) into the cavity 97 through the resin passageway 98 and the gate 91 for filling the cavity 97 with the resin material in order to mold the resin molding 24 by injection molding or transfer molding.

The resin material injected through the gate 91 flows from a large diameter end of the cavity 97 toward an opposite small diameter end. Thus, the large diameter end (top end) of the cavity 97 corresponds to an upstream side of resin flow, and the small diameter end (bottom end) of the cavity 97 corresponds to a downstream side of resin flow. Accordingly, gas is gradually forced from the top end toward the bottom end by resin flow in the cavity 97, and is discharged to the outside through the gas-vent passage 95 between the lower mold 82 and the ejection rod 93.

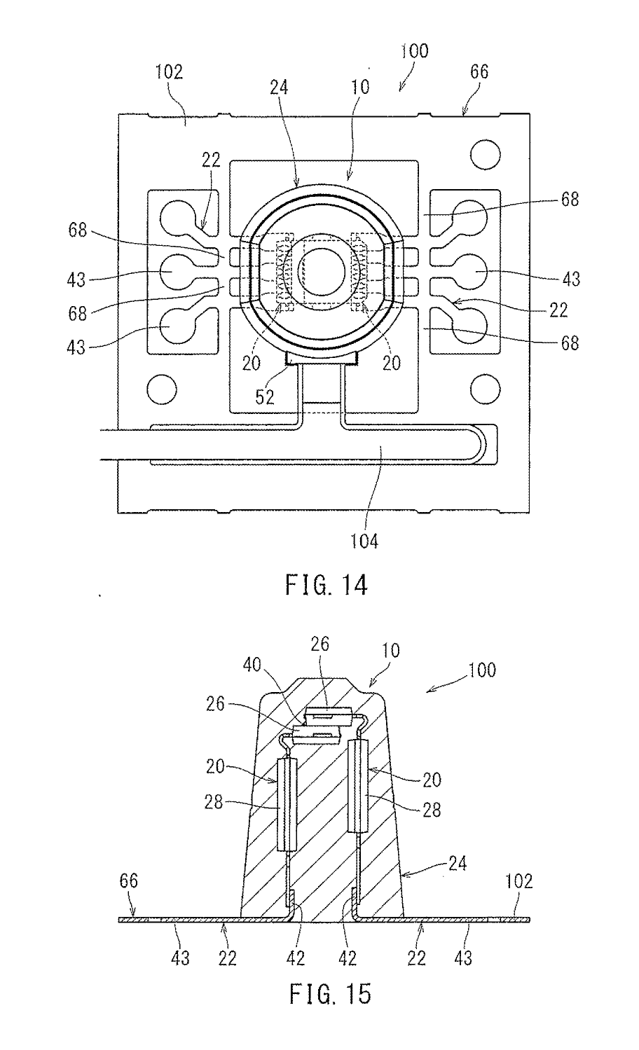

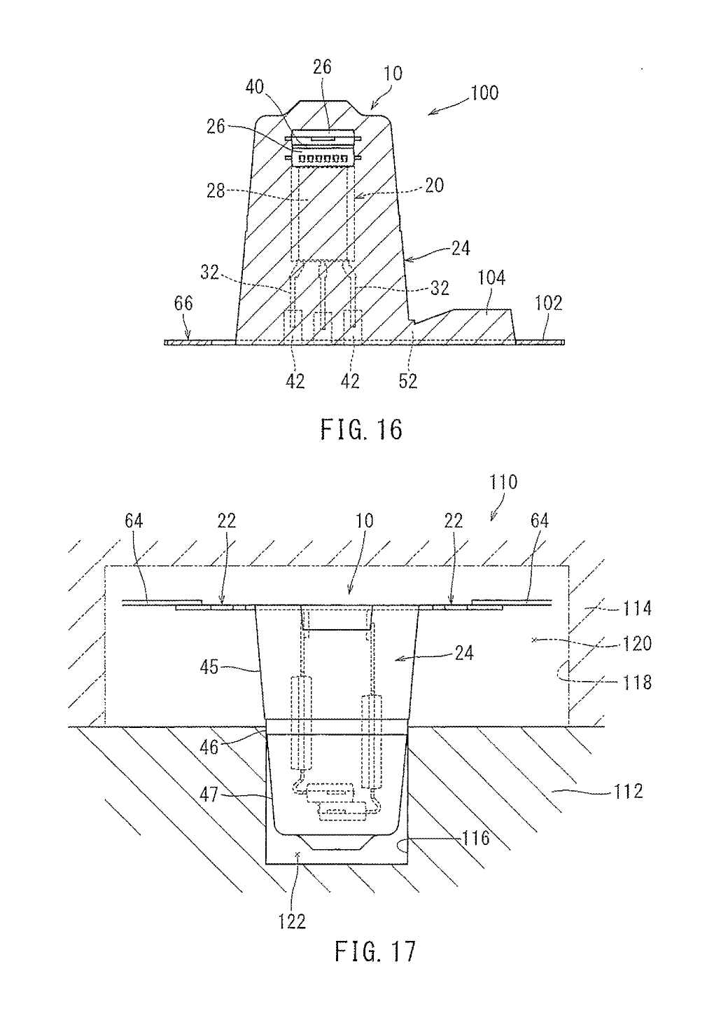

After shaping and hardening of the resin molding 24, the mold 80 is opened. Then, the ejection rod 93 is moved upward in order to eject a molding product (referred to as “sensor molding product 100”) from the lower mold 82. FIG. 14 is a top view of the sensor molding product 100. FIG. 15 is a sectional front view of the sensor molding product 100. FIG. 16 is a sectional side view of the sensor molding product 100. As shown in FIGS. 14-16, a remaining part 102 (excluding the tie-bars 68 of the hoop material 66 and the sensor terminals 22) is removed from the sensor molding product 100. Also, a molded passage 104 (refer to FIGS. 14 and 16) formed by the resin passageway 98 is removed from the sensor molding product 100. In this step, the molded passage 104 is divided from the convex 52 of the resin molding 24. Thus, the rotational angle sensor 10 (refer to FIGS. 2-4) is completed.

According to the rotational angle sensor 10, because the sensor portions 26 of the sensor ICs 20 are fixedly coupled to each other by the adhesive 40, a retaining member for positioning the sensor ICs 20 used in conventional practice (e.g., refer to Japanese Laid-Open Patent Publication No. 2007-92608) is omitted, and the number of components and the number of steps required for assembly process is fewer than that found in conventional practice. Further, because the sensor ICs 20 are completely located within the resin molding 24, short circuits which may be caused by an ingress of dew condensation can be prevented. This particularly helps should the resin molding 24 has a non-covered area where a part of the sensor IC 20 is exposed to the outside. Further, such a configuration can prevent cracks at the non-covered area of the resin molding 24, which are typically caused by stress due to changes in temperature. Accordingly, the quality and appearance of the product can be improved.

The adhesive 40 binds the two surfaces 26a and 26b which form the L-shaped corner in a state where the sensor portions 26 of the sensor ICs 20 are arranged in their thickness direction (FIGS. 4 and 11). Thus, as compared to when the adhesive 40 is put between a top surface of the lower sensor portion 26 and a bottom surface of the upper sensor portion 26, this configuration allows for a decrease in the variety of positions for the sensor portions in the thickness direction.

Because the connecting leads 32 of the sensor ICs 20 are connected to the sensor terminals 22 without being bent, a bending step of the connecting leads 32 can be omitted. Further, it is necessary to adjust the position of each sensor portions 26 when connecting the connecting leads 32 to the sensor terminals 22 when the bent connecting leads 32. However, because the connecting leads 32 are not bent in this embodiment, such step for adjusting the positions of the sensor portions 26 can be omitted.

The resin molding 24 is formed in a columnar shape from the resin material injected from the gate 91 (refer to FIG. 13) positioned at one end (large diameter end) in the axial direction. The tapered projection 56 is formed on the opposite end (small diameter end) of the resin molding 24 in the axial direction, (i.e., the end of the downstream side of the resin flowing during the molding process). Thus, in the forming process of the resin molding 24, because gas is forced toward the bottom side forming the top end of the projection 56 in the cavity 97 of the mold 80, the generation of non-covered areas and voids in the resin molding 24 can be prevented.

The resin material for the resin molding 24 is injected from the side surface of one end of the gate 91 (the large diameter end) in the axial direction. Thus, when simultaneously forming a plurality of the resin moldings 24, a plurality of the cavities 97 for each forming the resin molding 24 can be compactly arranged on both sides of the common resin passageway 98.

The resin molding 24 is formed in a tapered shape having cross-sections gradually decreasing from the upstream end (large diameter end) of the resin flow during the molding process toward the downstream end (small diameter end). Thus, as gas can be easily forced to the end for forming the top end of the resin molding 24 in the cavity 97 of the mold 80 during the molding process, the generation of non-covered areas, voids or the like in the resin molding 24 can be prevented.

The resin molding 24 has three tapered sections 45, 46 and 47 continuing in the axial direction. The taper angle 460 of the middle tapered section 46 is smaller than the taper angle 450 of the tapered section 45 and the taper angle 470 of the tapered section 47 (FIG. 2). Accordingly, the middle tapered section 46 serves as a boundary between the base part and the top part.

A mold 110 for insertion molding of the rotational angle sensor 10 into the connector side member 60 will be described. FIG. 17 is a sectional front view of the mold 110 during a next step (for molding the connector side member 60). As shown in FIG. 17, the mold 110 is composed of a lower mold 112 and an upper mold 114. In this embodiment, the lower mold 112 is fixed, and the upper mold 114 is movable. The upper mold 114 can be moved in the vertical direction. That is, when the upper mold 114 is moved downward with respect to the lower mold 112, the mold 110 is closed. When the upper mold 114 is moved upward with respect to the lower mold 112, the mold 110 is opened. The lower mold 112 has a recess 116 for receiving the top end (on the small diameter side) of the resin molding 24 of the rotational angle sensor 10. An open edge of the recess 116 is formed to fit with the middle tapered section (boundary section) 46 with no or almost no space between them. The upper mold 114 has a shaping recess 118 for forming an outer surface of the resin molding 62 of the connector side member 60.

For forming the resin molding 62 of the connector side member 60 with the mold 110, the rotational angle sensor 10 is put on the lower mold 112 in a state where the mold 110 is open. That is, the top end (on the small diameter side) of the resin molding 24 of the rotational angle sensor 10 is inserted into the recess 116 of the lower mold 112. In this step, the middle tapered section (boundary section) 46 of the resin molding 24 is fitted with the open edge of the recess 116 with no or almost no space between them. Then, the lower mold 112 is moved downward with respect to the upper mold 114 for closing the mold 110. Thus, a cavity 120 for shaping the resin molding 62 is formed between the upper mold 114 and the lower mold 112. In this state, a resin injection unit (not shown) injects a resin material (melting resin) into the cavity 120 for filling the cavity 120 with the resin material in order to form the resin molding 62 by injection molding or transfer molding. After cooling the resin material for hardening the resin molding 62, the mold 110 is opened, and an ejection rod (not shown) is moved upward in order to eject a product (the connector side member 60) from the lower mold 112.

In molding the base part of the resin molding 24 with the resin material (the resin molding 62) the top end of the resin molding 24 is inserted into the recess 116 of the lower mold 112 of the mold 110. When this occurs, the middle tapered section (boundary section) 46 is fitted with the open edge of the recess 116 with no or almost no space between them in order to inhibit formation of a burr. Further, because a predetermined space 122 between the resin molding 24 and an inner circumference of the recess 116 of the lower mold 112 (with the exception that its open edge is maintained), friction resistance between the lower mold 112 and the resin molding 24 during ejection of the connector side member (product) 60 can be decreased. Thus, pushing force of the ejection rod against the connector side member (product) 60 can be decreased.

Each pair of the sensor terminals 22 adjacent to each other (i.e., a combination of the front sensor terminal 22 and the center sensor terminal 22 or a combination of the center sensor terminal 22 and the rear sensor terminal 22) are arranged in parallel. The sensor terminals 22 are shaped such that the interval between them are increased on the side of the terminal areas 43 and the front or rear sensor terminals 22 are longer than the center sensor terminal 22 (FIG. 3). Because the distance between the terminal areas 43 of the pair of sensor terminals 22 arranged in parallel is increased, it is able to easily connect the connector terminals 64 to the terminal areas 43 of the sensor terminals 22. Further, due to the longer (front or rear) sensor terminal 22, it is able to effectively adsorb stress caused, for example, during a connection step of the connector terminals 64 can be effectively absorbed.

The resin molding 24 has an equivalent linear expansion coefficient as the covering members 36 of the sensor portions 26 of the sensor ICs 20. Thus, expansion and contraction of the resin molding 24 caused by temperature changes will not have a significant detrimental influence on the sensor ICs 20.

The top end surface of the projection 56 of the resin molding 24 is shaped by the ejection rod 93 (in detail, its top end surface) during formation of the resin molding 24 (FIGS. 12 and 13). Thus, the top end surface of the projection 56 of the resin molding 24 can be formed along with the ejection rod 93 and the product (i.e., the rotational angle sensor 10) can be ejected with the ejection rod 93. In addition, the strength of the ejection rod 93 can be increased by increasing the diameter of the ejection rod 93 of the mold 80. Further, a compact mold 80 can be created using a single ejection rod 93.

The resin molding 24 is formed with the mold 80 having the gas-vent passage 95 between the ejection rod 93 and the lower mold 82 (FIGS. 12 and 13). Thus, mold 80 is able to efficiently discharge gas from the cavity 97 through the gas-vent passage 95 between the lower mold 82 and the ejection rod 93 during formation of the resin molding 24. Accordingly, it is able to prevent generation of, e.g., non-covered area and void in the resin molding 24.

The outer circumferential surface and the top end surface of the resin molding 24 are smoothly continued via the convex curved area 54 having the predetermined radius, and the top end surface of the resin molding 24 and the outer circumference of the projection 56 are smoothly continued via the concave curved area 58 having the predetermined radius (FIG. 2). Thus, the resin material is able to smoothly flow during formation of the resin molding 24 and voids caused by gas entrapment can be decreased.

Embodiments of the present disclosure are not limited to the above-described embodiments, and can be modified without departing from the scope and the spirit of the disclosure. For example, the principles disclosed herein can be applied to various rotational angle sensors for detecting rotational angle of a rotatable member. The sensor ICs 20 can be replaced with hole devices or hole ICs, etc. The computing portions 28 of the sensor ICs 20 do not restrict the subject-matter of this disclosure. The mold 80 can have a plurality of gates. The adhesive 40 can be applied between the contact surfaces of the sensor portions 26 of the sensor ICs 20. The resin molding 24 can have four or more tapered sections.

1. A rotation angle detector for detecting magnetic change caused by rotation of a rotatable member, comprising:
a resin molding;
a pair of magnetic property detection members each having a plurality of connecting leads and a sensor portion for detecting a magnetic change caused by the rotatable member; and
a plurality of sensor terminals, each sensor terminal individually connected to one of the plurality of connecting leads; and
wherein the magnetic property detection members are located within the resin molding and wherein the sensor portions of the magnetic property detection members are fixedly coupled to each other by an adhesive.

2. The rotation angle detector according to claim 1, wherein the sensor portions are arranged such that they are in contact with each other in their thickness direction and wherein the adhesive binds a top surface of a lower sensor portion to an end surface of an upper sensor portion at an L-shaped inner corner formed by the top surface and the end surface.

3. The rotation angle detector according to claim 1, wherein each of the magnetic property detection members has a computing portion and a plurality of L-shaped coupling leads, where the sensor portion of each magnetic property detection member is connected to one side of the computing portion via the coupling leads, the computing portion is configured to output signals depending on the magnetic change detected from signals output from the sensor portion, and the plurality of the connecting leads are coupled to the opposite side of the computing portion;
wherein the magnetic property detection members are positioned to face each other such that their sensor portions are arranged such that they are in contact with each other in their thickness direction; and
wherein the connecting leads are connected to the sensor terminals without being bent.

4. The rotation angle detector according to claim 1, wherein the resin molding is formed in a columnar shape from a resin material injected from a gate positioned to correspond to one end of the resin molding in an axial direction; and
wherein the resin molding has a tapered projection at an opposite end in the axial direction.

5. The rotation angle detector according to claim 4, the resin material is injected from the gate positioned to correspond to a side surface of the one end of the resin molding in the axial direction.

6. The rotation angle detector according to claim 1, wherein the resin molding is formed in a tapered shape having cross-sections gradually decreasing from one end on an upstream side of resin flow during formation of the resin molding toward an opposite end on a downstream side of resin flow.

7. The rotation angle detector according to claim 6, wherein the resin molding has at least three tapered sections in the axial direction; and
a taper angle of the middle tapered section is smaller than taper angles of the other tapered sections.

8. The rotation angle detector according to claim 1, wherein at least two of the sensor terminals, which are adjacent to each other, are arranged in parallel,
wherein each of the two sensor terminals has a terminal end on the opposite side of the magnetic property detection members;
wherein the interval between the two sensor terminals increases on the side of the terminal ends; and
wherein a first sensor terminal is longer than a second sensor terminal.

9. The rotation angle detector according to claim 1, wherein the resin molding has the same linear expansion coefficient as a resinous coating of the sensor portions of the magnetic property detection members.

10. The rotation angle detector according to claim 4, wherein the projection of the resin molding has a top end surface; and
wherein the top end surface is shaped by an ejection rod of a mold during formation of the resin molding.

11. The rotation angle detector according to claim 10, wherein the resin molding is shaped by the mold having a gas-vent passage between the ejection rod and a mold component having the ejection rod.
